(19) United States
(12) Patent Application Publication
(10) Pub. No.: US 2025/0293087 A1
(43) Pub. Date: Sep. 18, 2025

(54) SEMICONDUCTOR DEVICE INCLUDING SUPER VIA AND METHOD FOR MANUFACTURING THE SAME

(71) Applicant: TAIWAN SEMICONDUCTOR MANUFACTURING COMPANY, LTD., Hsinchu (TW)

(72) Inventors: Cian-Yu CHEN, Hsinchu (TW); Ching-Fu YEH, Hsinchu (TW); Meng-Pei LU, Hsinchu (TW); Chin-Lung CHUNG, Hsinchu (TW); Yun-Chi CHIANG, Hsinchu (TW); Shin-Yi YANG, Hsinchu (TW)

(73) Assignee: TAIWAN SEMICONDUCTOR MANUFACTURING COMPANY, LTD., Hsinchu (TW)

(21) Appl. No.: 18/603,824

(22) Filed: Mar. 13, 2024

(51) Int. Cl. H01L 21/768; H01L 23/522; H01L 23/535

(52) U.S. Cl. CPC H01L 21/76895; H01L 21/76805; H01L 21/76843; H01L 21/76858; H01L 21/76862; H01L 23/5226; H01L 23/535

(57) ABSTRACT

A method for manufacturing a semiconductor device includes: forming a multi-layered interconnect structure on a semiconductor substrate, the multi-layered interconnect structure including interconnect layers and etch stop layers alternately disposed on the semiconductor substrate; forming a via opening to penetrate at least one of the interconnect layers to expose one of metal lines of one of the interconnect layers disposed below the at least one of the interconnect layers; and forming a super via in the via opening to penetrate the at least one of the interconnect layers so that the super via is connected to the one of the metal lines of the one of the interconnect layers disposed below the at least one of the interconnect layers.

### BACKGROUND

An interconnect structure with a single or dual damascene architecture is usually formed in a middle end of line (MEOL) process and/or a back end of line (BEOL) process by sequentially and separately depositing a barrier layer and a liner layer, followed by filling a metal material (e.g., cupper (Cu)) into an opening defined by the liner layer. The barrier layer is made of metal nitride, and is used for preventing the metal material from diffusing into neighboring sensitive regions. Copper diffusion may negatively affect performances of a semiconductor device, or may even lead to complete failure of the semiconductor device. The liner layer is made of a single metal, and is used for permitting the metal material to be deposited thereon.

### BRIEF DESCRIPTION OF THE DRAWINGS

Aspects of the present disclosure are best understood from the following detailed description when reads with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 6 are schematic views showing some stages of the method depicted in FIG. 1.

FIGS. 7 to 9 are schematic views illustrating some variants of a semiconductor device manufactured by the method depicted in FIG. 1 in accordance with some alternative embodiments.

FIGS. 10 to 14 are schematic views showing some stages of the method depicted in FIG. 1 in accordance with some alternative embodiments.

FIGS. 15 to 17 are schematic views showing some stages of the method depicted in FIG. 1 in accordance with some alternative embodiments.

FIGS. 18 to 44 are schematic views illustrating some variants of a semiconductor device manufactured by the method depicted in FIG. 1 in accordance with some alternative embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “bottom,” “below,” “uppermost,” “lowermost,” “upper,” “lower,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

An interconnect structure with a single or dual damascene architecture is usually formed in a middle end of line (MEOL) process and/or a back end of line (BEOL) process by sequentially and separately depositing a barrier layer and a liner layer, followed by filling a metal material (e.g., cupper (Cu)) into an opening defined by the liner layer. The barrier layer is made of metal nitride, and is used for preventing the metal material from diffusing into neighboring sensitive regions. Copper diffusion may negatively affect performance of a semiconductor device, or may even lead to complete failure of the semiconductor device. The liner layer is made of a single metal, and is used for permitting the metal material to be deposited thereon. The integration density of various electronic components, for example, but not limited to, transistors, diodes, resistors, capacitors, etc., is being improved continuously in the semiconductor industry by continual reduction in minimum feature sizes. As the feature sizes decrease, an interconnect structure (for example, a via structure) formed by sequentially and separately depositing a barrier layer and a liner layer, followed by filling a metal material into an opening defined by the liner layer, may suffer high via resistance. The present disclosure is directed to a semiconductor device with reduced via resistance which is achieved by providing a super via structure including a barrier/liner dual-functional layer (i.e., a dual-functional layer serving as both a barrier layer and a liner layer).

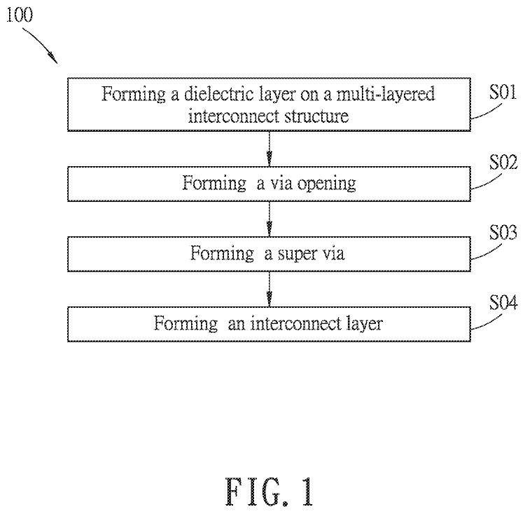

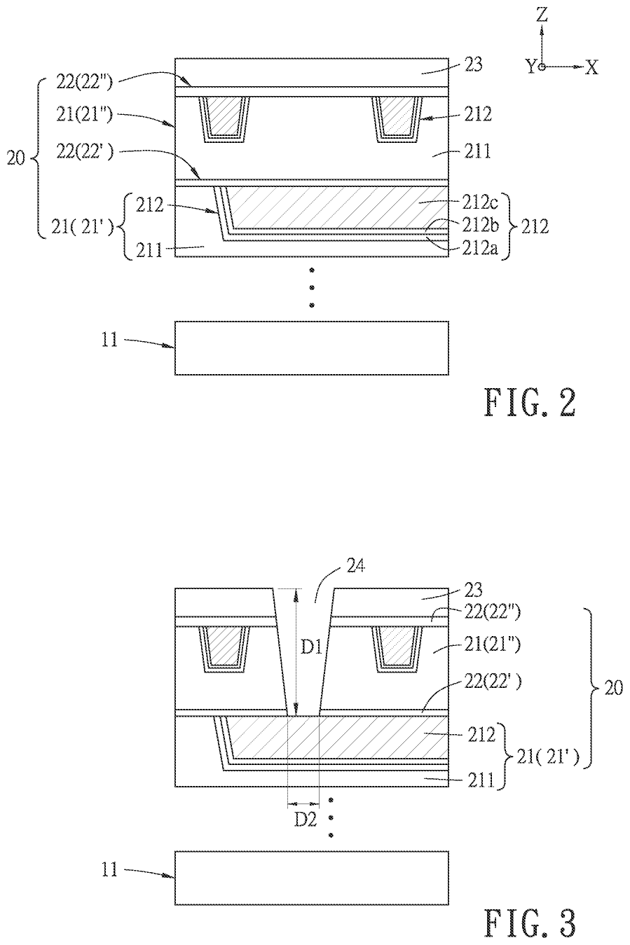

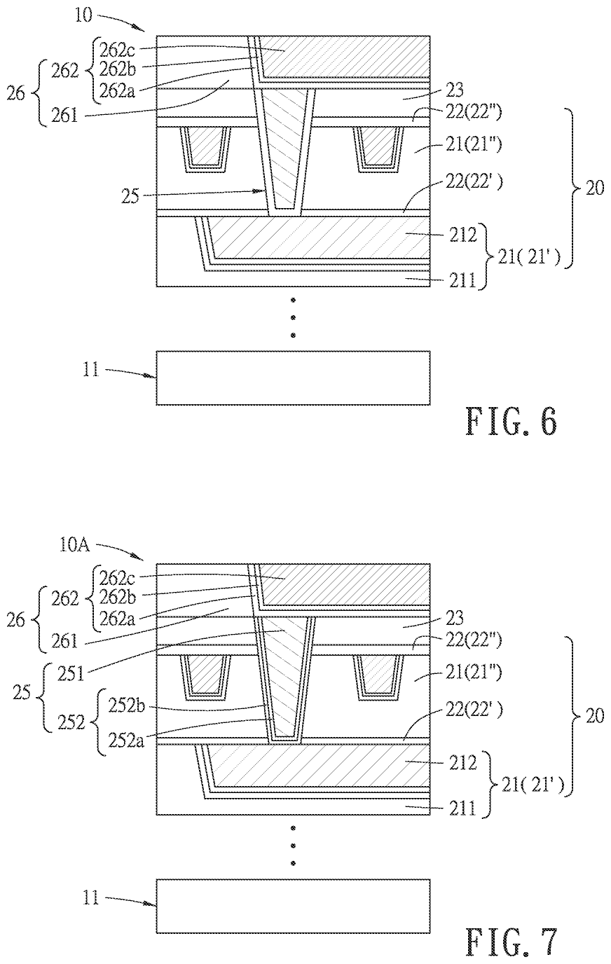

FIG. 1 illustrates a method 100 for manufacturing a semiconductor device in accordance with some embodiments. FIGS. 2 to 6 are schematic views illustrating some stages of the method 100 as depicted in FIG. 1 in accordance with some embodiments. Additional steps can be provided before, after or during the method 100, and some of the steps described herein may be replaced by other steps or be eliminated. Similarly, further additional features may be present in a semiconductor device 10 shown in FIG. 6, and/or features present may be replaced or eliminated in additional embodiments.

Referring to FIG. 1 and the example illustrated in FIG. 2, the method 100 begins at step S01, where a dielectric layer 23 is formed on a multi-layered interconnect structure 20, which is disposed on a semiconductor substrate 11.

In some embodiments, the semiconductor substrate 11 may include, for example, but not limited to, an elemental semiconductor or a compound semiconductor. The elemental semiconductor includes a single species of atoms, such as silicon (Si) or germanium (Ge) in column XIV of the periodic table, and may be in a crystal form, a polycrystalline form, or an amorphous form. Other suitable elemental semiconductor materials are within the contemplated scope of the present disclosure. The compound semiconductor includes two or more elements, and examples thereof may include, but not limited to, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 11 may include a multilayer compound semiconductor substrate. In some embodiments, the semiconductor substrate 11 may be a semiconductor on insulator (SOI) (e.g., silicon germanium on insulator (SGOI)). Generally, an SOI substrate includes a layer of a semiconductor material such as epitaxial silicon, germanium, silicon germanium, or combinations thereof. Other suitable materials are within the contemplated scope of the present disclosure. The SOI substrate may be doped with a P-type dopant, for example, but not limited to, boron (Br), aluminum (Al), or gallium (Ga). Other suitable P-type dopant materials are within the contemplated scope of the present disclosure. Alternatively, the SOI substrate may be doped with an N-type dopant, for example, but not limited to, nitrogen (N), phosphorus (P), or arsenic (As). Other suitable N-type dopant materials are within the contemplated scope of the present disclosure. In some embodiments, the semiconductor substrate 11 may further include various active regions, for example, the active regions configured for an N-type metal oxide semiconductor transistor device (NMOS) or the active regions configured for a P-type metal oxide semiconductor transistor device (PMOS).

The multi-layered interconnect structure 20 includes a plurality of interconnect layers 21 and a plurality of etch stop layers 22 alternately disposed on the semiconductor substrate 11 in a Z direction normal to the semiconductor substrate 11. In some embodiments, an uppermost one of the etch stop layers 22 is disposed over an uppermost one of the interconnect layers 21 such that an uppermost layer of the multi-layered interconnect structure 20 is the uppermost one of the etch stop layers 22. In some embodiments, a lowermost one of the interconnect layers 21 is disposed below a lowermost one of the etch stop layers 22 such that a lowermost layer of the multi-layered interconnect structure 20 is the lowermost one of the interconnect layers 21. In some embodiments, the multi-layered interconnect structure 20 includes a lower interconnect layer 21′, an upper interconnect layer 21″, a lower etch stop layer 22′, and an upper etch stop layer 22″. The lower etch stop layer 22′ is disposed on the lower interconnect layer 21′ opposite the semiconductor substrate 11. The upper interconnect layer 21″ is disposed on the lower etch stop layer 22′ opposite to the lower interconnect layer 21′. The upper etch stop layer 22″ is disposed on the upper interconnect layer 21″ opposite to the lower etch stop layer 22′.

In some embodiments, each of the etch stop layers 22 may independently include silicon nitride, silicon nitride doped with carbon, silicon oxide, silicon oxynitride, silicon oxynitride doped with carbon, amorphous carbon material, silicon carbide, silicon oxycarbide, other nitride materials, other carbide materials, aluminum oxide, other metal oxides, aluminum nitride, other metal nitrides (e.g., titanium nitride, or the like), boron nitride, boron carbide, tungsten carbide, and other low-k dielectric materials or low-k dielectric materials doped with one or more of carbon, nitrogen, and hydrogen. Other suitable materials are within the contemplated scope of the present disclosure. The materials for the etch stop layers 22 may the same as or different from each other. Each of the etch stop layers 22 may be a single-layered configuration, a bi-layered configuration, or a multi-layered configuration. In some embodiments, each of the etch stop layers 22 may be formed by a suitable deposition process as is known in the art of semiconductor fabrication, such as physical vapor deposition (PVD), chemical vapor deposition (CVD), atomic layer deposition (ALD), plasma-enhanced ALD (PEALD), or plasma-enhanced CVD (PECVD). Other suitable deposition techniques are within the contemplated scope of the present disclosure.

Each of the interconnect layers 21 includes a dielectric layer 211 (i.e., an inter-metal dielectric layer) and a plurality of metal lines 212 disposed in the dielectric layer 211 and separated from each other. In some embodiments, the metal lines 212 of the lower interconnect layer 21′ extend in an X direction transverse to the Z direction and parallel to the semiconductor substrate 11, and the metal lines 212 of the upper interconnect layer 21″ extend in a Y direction transverse to the X direction and the Z direction. In some embodiments, the dielectric layer 211 includes, for example, but not limited to, silicon oxide, silicon nitride, silicon carbide, silicon oxycarbide, silicon oxycarbide doped with hydrogen, silicon oxynitride, or other low dielectric constant (low-k) dielectric materials. Other suitable dielectric materials are within the contemplated scope of the present disclosure. In some embodiments, the dielectric layer 211 has a dielectric constant (k) value ranging from about 1 to about 5. In some embodiments, each of the metal lines 212 has a dimension ranging from about 1 nanometer (nm) to about 250 nm, and includes a barrier layer 212a, a liner layer 212b disposed on the barrier layer 212a, and a bulk metal region 212c disposed on the liner layer 212b and separated from the barrier layer 212a by the liner layer 212b. The barrier layer 212a and the liner layer 212b are formed separately and sequentially. In some embodiments, the barrier layer 212a may include, for example, but not limited to, tantalum (Ta), zinc (Zn), manganese (Mn), zirconium (Zr), titanium (Ti), hafnium (Hf), niobium (Nb), vanadium (V), chromium (Cr), scandium (Sc), yttrium (Y), silicon (Si), tungsten (W), molybdenum (Mo), or aluminum (Al). Other suitable materials are within the contemplated scope of the present disclosure. In some embodiments, the liner layer 212b may include, for example, but not limited to, cobalt (Co), ruthenium (Ru), or tantalum (Ta). Other suitable materials are within the contemplated scope of the present disclosure. In some embodiments, the bulk metal region 212c includes copper (Cu), Co, Ru, nickel (Ni), or W. Other suitable materials are within the contemplated scope of the present disclosure.

In some embodiments, each of the interconnect layers 21 may be formed using a single damascene processes. In the single damascene process, the dielectric layer 211 is formed by a suitable deposition process as is known in the art of semiconductor fabrication, such as PVD, CVD, ALD, PEALD, or PECVD. Other suitable deposition techniques are within the contemplated scope of the present disclosure. A plurality of trenches (not shown) are formed in the dielectric layer 211 by patterning the dielectric layer 211 using a suitable etching process (for example, but not limited to, a dry etching process or a wet etching process) through an opening pattern formed in a patterned mask layer (not shown) disposed on the dielectric layer 211. A barrier material layer for forming the barrier layer 212a is conformally deposited on the dielectric layer 211 formed with the trenches, a liner material layer for forming the liner layer 212b is then conformally deposited on the barrier material layer, and a bulk metal layer for forming the bulk metal region 212c is formed on the liner material layer to fill the trenches. In some embodiments, each of the barrier material layer, the liner material layer, and the bulk metal layer may be formed independently by a suitable deposition process as is known in the art of semiconductor fabrication, such as electrochemical plating (ECP), electroless deposition (ELD), PVD, CVD, ALD, PEALD, or PECVD. Other suitable deposition techniques are within the contemplated scope of the present disclosure. Excess of the barrier material layer, excess of the liner material layer, and excess of the bulk metal layer over the dielectric layer 211 are removed by a planarization process (for example, but not limited to, a chemical mechanical planarization (CMP) process) to form the metal lines 212.

The dielectric layer 23 is formed on the multi-layered interconnect structure 20 by a suitable deposition process which may be the same as or similar to that for forming the dielectric layer 211, and includes a dielectric material which may be the same as or similar to that of the dielectric layer 211, and the details thereof are omitted for the sake of brevity.

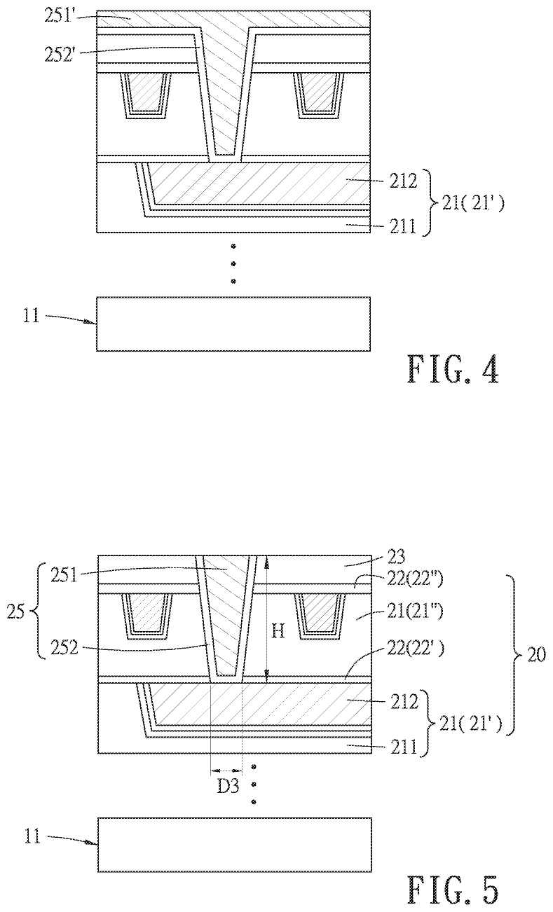

Referring to FIG. 1 and the example illustrated in FIG. 3, the method 100 proceeds to step S02, where a via opening 24 is formed. The via opening 24 is formed to penetrate the dielectric layer 23 and at least one of the interconnect layers 21 so as to expose one of the metal lines 212 of one of the interconnect layers 21 disposed below the at least one of the interconnect layers 21. In some embodiments, the via opening 24 penetrates the dielectric layer 23, the upper etch stop layer 22″, the upper interconnect layer 21″, and the lower etch stop layer 22′ to expose one of the metal lines 212 of the lower interconnect layer 21′. In some embodiments, the via opening 24 has a depth (D1) ranging from about 1 nm to about 10000 nm, and a bottom dimension (D2) ranging from about 1 nm² to about 100000 nm². When the depth (D1) is greater than 10000 nm and/or when the bottom dimension (D2) is less than 1 nm², a super via 25 (which will be described hereinafter with reference to FIGS. 4 and 5) cannot be formed successfully. In some embodiments, the via opening is formed by patterning the dielectric layer 23, the etch stop layers 22, and the at least one of interconnect layers 21 disposed above the one of the interconnect layers 21 using a suitable etching process (for example, but not limited to, a dry etching process or a wet etching process) through an opening pattern formed in a patterned mask layer (not shown) disposed on the dielectric layer 23.

Referring to FIG. 1 and the examples illustrated in FIGS. 4 and 5, the method 100 proceeds to step S03, where a super via 25 is formed. The super via 25 penetrates the dielectric layer 23 and the at least one of the interconnect layers 21, and is connected to the one of the metal lines 212 of the one of the interconnect layers 21 disposed below the at least one of the interconnect layers 21. In some embodiments, the super via 25 penetrates the dielectric layer 23, the upper etch stop layer 22″, the upper interconnect layer 21″, and the lower etch stop layer 22′, and is connected to the one of the metal lines 212 of the lower interconnect layer 21′. In some embodiments, the super via 25 includes a bulk via region 251 and a barrier/liner dual-functional layer 252, which serves as both a barrier layer and a liner layer. The barrier/liner dual-functional layer 252 covers a side wall and a bottom surface of the bulk via region 251. In some embodiments, the super via 25 has a height (H) ranging from about 1 nm to about 10000 nm, and a bottom dimension (D3) ranging from about 1 nm² to about 100000 nm². In some embodiments, the barrier/liner dual-functional layer 252 includes an alloy which includes a first metal component and a second metal component different from the first metal component. In some embodiments, each of the first metal component and the second metal component includes a metal (for example, but not limited to, Co, Ru, Ta, Ti, W, Mo, Zn, Al, Mn, Zr, or other transition metals), a carbide of the metal, an oxide of the metal, a hydride of the metal, a nitride of the metal, a silicide of the metal, or combinations thereof. In some embodiments, the barrier/liner dual-functional layer 252 has a thickness ranging from about 5 Å to about 50 Å. In some embodiments, the bulk via region 251 includes a first metal component which includes Cu, silver (Ag), gold (Au), Ni, Co, iron (Fe), Ru, osmium (Os), rhenium (Re), iridium (Ir), platinum (Pt), palladium (Pd), rhodium (Rh), Al, W, Mo, other transition metals having promising conductive performance, or combinations thereof. In some embodiments, the bulk via region 251 includes the first metal component serving as a main metal component, and a second metal component serving as a doping component. In some embodiments, the second metal component includes a metal (for example, but not limited to, Al, Mn, Ti, Zr, Hf, Nb, Ta, Mo, W, Zn, V, Cr, Sc, Fe, Y, other metals, or combinations thereof), a silicide of the metal, an oxide of the metal, which possesses a barrier property, or combinations thereof. In some embodiments, the second metal component may be doped, into the first metal component, as a solid solution, an intermetallic compound, or a precipitate phase.

In some embodiments, the super via 25 may be formed by conformally depositing a barrier/liner dual-functional material layer 252′ for forming the barrier/liner dual-functional layer 252 on the structure shown in FIG. 3, depositing on the barrier/liner dual-functional material layer 252′, a bulk via material layer 251′ for forming the bulk via region 251 to fill the via opening 24 of the structure shown in FIG. 3, and removing excess of the barrier/liner dual-functional material layer 252′ and excess of the bulk via material layer 251′ over the dielectric layer 23 by a planarization process (for example, but not limited to, the CMP process). In some embodiments, the barrier/liner dual-functional material layer 252′ includes an alloy which includes a first metal component and a second metal component different from the first metal component. The first metal component and the second metal component of the barrier/liner dual-functional material layer 252′ are respectively the same as or similar to first metal component and the second metal component of the barrier/liner dual-functional layer 252, and the details thereof are omitted for the sake of brevity. In some embodiments, the barrier/liner dual-functional material layer 252′ may be formed by conformally depositing one of the first metal component and the second metal component, and then adding the other one of the first metal component and the second metal component by an atom doping process. In some embodiments, the bulk via material layer 251′ includes a first metal component which is the same as or similar to the first metal component of the bulk via region 251, and the details thereof are omitted for the sake of brevity. In some embodiments, the bulk via material layer 251′ includes the first metal component serving as a main metal component, and a second metal component serving as a doping component. In some embodiments, the second metal component of the bulk via material layer 251′ is the same as or similar to the second metal component of the bulk via region 251, and the details thereof are omitted for the sake of brevity.

In some embodiments, the barrier/liner dual-functional material layer 252′ may be conformally deposited by a suitable deposition process as is known in the art of semiconductor fabrication, such as ECP, ELD, PVD, CVD, ALD, PEALD, or PECVD. Other suitable deposition techniques are within the contemplated scope of the present disclosure. In some embodiments, an additional treatment can be performed before, after, or during the conformal deposition of the barrier/liner dual-functional material layer 252′ so as to enhance properties (such as, barrier and liner properties) of the barrier/liner dual-functional layer 252. In some embodiments, the additional treatment includes, for example, but not limited to, a gas soaking treatment, a precursor soaking treatment, a plasma treatment, or combinations thereof. Other suitable treatments are within the contemplated scope of the present disclosure. In some embodiments, the additional treatment may be performed using gas (for example, but not limited to, hydrogen (H₂) gas, nitrogen (N₂) gas, ammonia (NH₃) gas), hydrogen (H) radical, alcohol (for example, but not limited to, methanol), silane (NH₄), or any materials having hydrogen (H) bonds, hydroxyl (OH) bonds, nitrogen (N) bonds, carbon (C) bonds, silicon (Si) bonds, oxygen (O) bonds, alkyl (for example, but not limited to, methyl (CH₃—)) bonds, or metal bonds. In some embodiments, the plasma treatment may be performed using direct current (DC), radio frequency (RF), pulsed DC, medium frequency (MF), or high power impulse magnetron sputtering (HIPIMS). In some embodiments, the plasma treatment and/or the conformal deposition may be performed using a power ranging from about 50 W to about 15 kW.

In some embodiments, the bulk via material layer 251′ is deposited by a suitable deposition process as is known in the art of semiconductor fabrication, such as ECP, ELD, PVD, CVD, ALD, PEALD, or PECVD. Other suitable deposition techniques are within the contemplated scope of the present disclosure. In some embodiments, the bulk via material layer 251′ is deposited at a temperature ranging from about 25° C. to about 1000° C. If the bulk via material layer 251′ is deposited at a temperature greater than 1000° C., the structure shown in FIG. 5 may be damaged.

Referring to FIG. 1 and the examples illustrated in FIG. 6, the method 100 proceeds to step S04, where an interconnect layer 26 is formed. The interconnect layer 26 is formed on the dielectric layer 23 and the super via 25 to obtain the semiconductor device 10. The interconnect layer 26 includes a dielectric layer 261 (i.e., an inter-metal dielectric layer) and a plurality of metal lines 262 disposed in the dielectric layer 261 and separated from each other. In some embodiments, the metal lines 262 of the interconnect layer 26 extend in the X direction. The material and the process for forming the dielectric layer 261 may be the same as or similar to those for forming the dielectric layer 211 described above with reference to FIG. 2, and the details thereof are omitted for the sake of brevity. The configuration of the metal lines 262 may be the same as or similar to that of the metal lines 212 described above with reference to FIG. 2, and includes a barrier layer 262a, a liner layer 262b disposed on the barrier layer 262a, and a bulk metal region 262c disposed on the liner layer 262b and separated from the barrier layer 262a by the liner layer 262b. The materials and the processes for forming the metal lines 262 may be the same as or similar to those for forming the metal lines 212 described above with reference to FIG. 2, and the details thereof are omitted for the sake of brevity. One of the metal lines 262 of the interconnect layer 26 and a corresponding one of the metal lines 212 of the one of the interconnect layers 21 disposed below the at least one of the interconnect layers 21 of the multi-layered interconnect structure 20 are electrically connected to each other through the super via 25, which penetrates the dielectric layer 23 and the at least one of the interconnect layers 21 of the multi-layered interconnect structure 20. In some embodiments, the super via 25 penetrates the dielectric layer 23, the upper etch stop layer 22″, the upper interconnect layer 21″, and the lower etch stop layer 22′ of the multi-layered interconnect structure 20.

Referring to the example illustrated in FIG. 7, in a semiconductor device 10A in accordance with some alternative embodiments, the barrier/liner dual-functional layer 252 has a multi-layered configuration, and includes at least two sub-layers. In some embodiments, the barrier/liner dual-functional layer 252 includes an inner sub-layer 252a covering the side wall and the bottom surface of the bulk via region 251, and an outer sub-layer 252b covering the inner sub-layer 252a and separated from the bulk via region 251 by the inner sub-layer 252a. In this case, in some embodiments, the inner sub-layer 252a of the barrier/liner dual-functional layer 252 includes a first metal component, the outer sub-layer 252b of the barrier/liner dual-functional layer 252 includes a second metal component different from the first metal component, and the barrier/liner dual-functional layer 252 further includes an alloy which is formed between the inner sub-layer 252a and the outer sub-layer 252b and which includes the first metal component and the second metal component. In some embodiments, each of the first metal component and the second metal component includes a metal (for example, but not limited to, Co, Ru, Ta, Ti, W, Mo, Zn, Al, Mn, Zr, or other transition metals), a carbide of the metal, an oxide of the metal, a hydride of the metal, a nitride of the metal, a silicide of the metal, or combinations thereof.

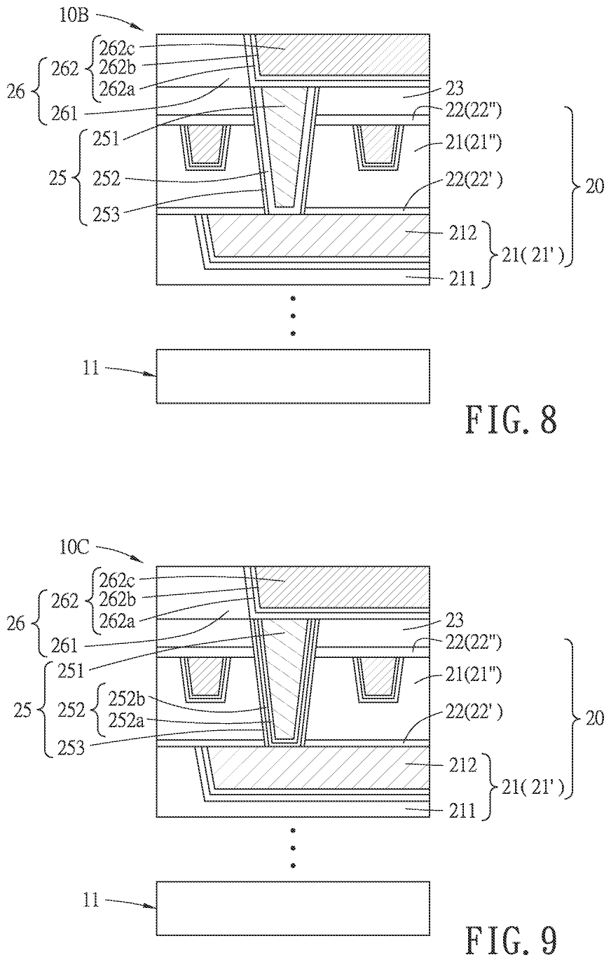

Referring to the example illustrated in FIG. 8, in a semiconductor device 10B in accordance with some alternative embodiments, when the bulk via material layer 251′ described above for forming the bulk via region 251 includes the first metal component serving as the main metal component and the second metal component serving as the doping component as described above with reference to FIGS. 4 and 5, the super via 25 is further formed with a self-forming barrier layer 253, which includes the second metal component serving as the doping component, which covers a side wall of the barrier/liner dual-functional layer 252, and which is isolated from the bulk via region 251 by the barrier/liner dual-functional layer 252. The self-forming barrier layer 253 may be formed by diffusion of the second metal component (i.e., the doping component) through the barrier/liner dual-function layer 252 during the conformal deposition of the bulk via material layer 251′ or by an annealing process performed after the conformal deposition. In some embodiments, the annealing process is a rapid thermal annealing (RTA) process, a laser annealing process, a furnace annealing process, or combinations thereof. In some embodiments, the annealing process is performed at a temperature ranging from about 100° C. to about 1400° C. If the temperature for the annealing process is lower than 100° C., the self-forming barrier layer 253 may not be formed. If the temperature for the annealing process is higher than 1400° C., the structure shown in FIG. 7 may be damaged.

Referring to the example illustrated in FIG. 9, a semiconductor device 10C in accordance with some alternative embodiments has a configuration similar to that of the semiconductor device 10A shown in FIG. 7, except that the super via 25 of the semiconductor device 10C further includes the self-forming barrier layer 253 described above with reference to FIG. 8. The self-forming barrier layer 253 covers the side wall of the barrier/liner dual-functional layer 252 and is isolated from the bulk via region 251 by the barrier/liner dual-functional layer 252.

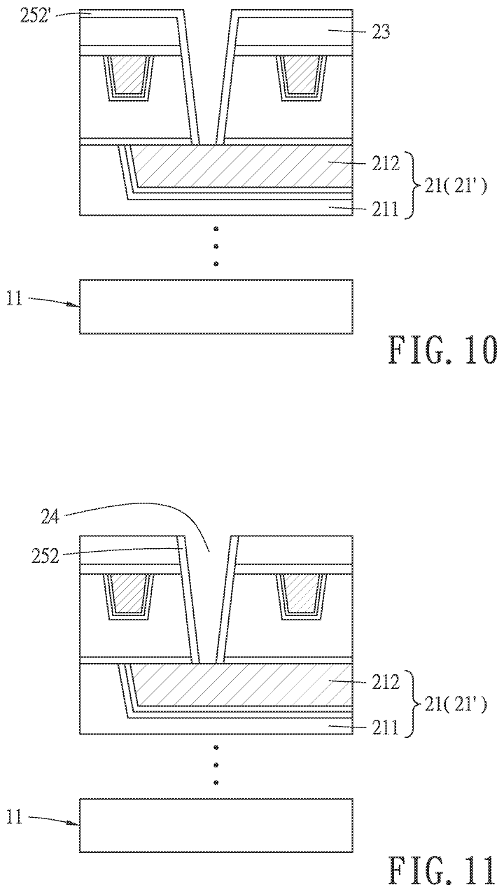

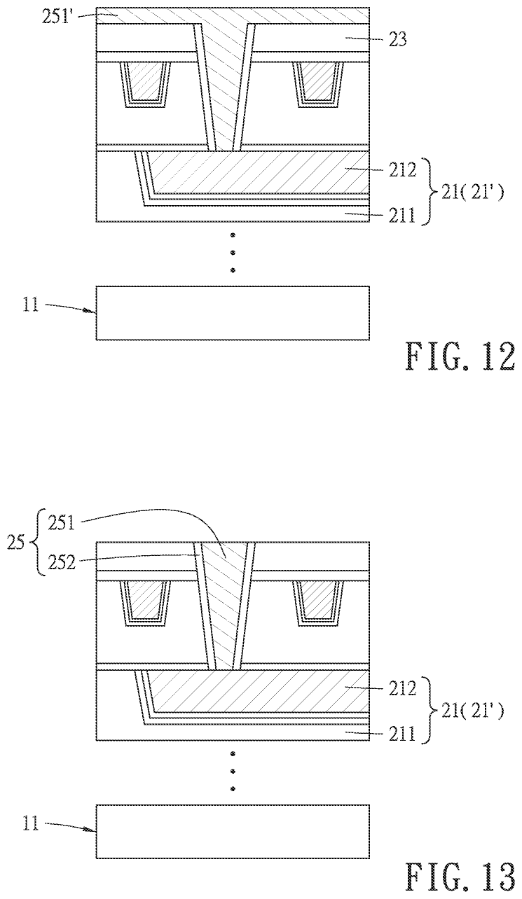

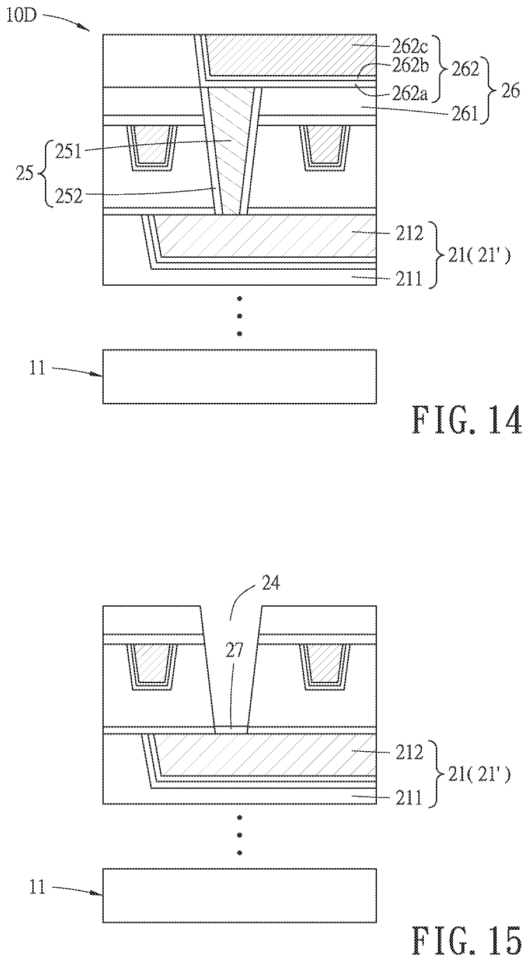

Referring to FIG. 1 and the examples illustrated in FIGS. 10 to 13, in some alternative embodiments, step S03 (i.e., formation of the super via 25) is performed by conformally depositing the barrier/liner dual-functional material layer 252′ on the structure shown in FIG. 3 to form a structure shown in FIG. 10, removing portions of the barrier/liner dual-functional material layer 252′ on the dielectric layer 23 and on one of the metal lines 212 of the lower interconnect layer 21′ by a suitable anisotropic etching process (for example, but not limited to, an anisotropic dry etching process) to form the barrier/liner dual-functional layer 252 (see FIG. 11), depositing the bulk via material layer 251′ on the structure shown in FIG. 11 to fill the via opening 24, and removing excess of the bulk via material layer 251′ over the dielectric layer 23 by a planarization process (for example, but not limited to, the CMP process) to form the super via 25. Therefore, a semiconductor device 10D shown in FIG. 14 is obtained after performing step S04 (i.e., formation of the interconnect layer 26 described above with reference to FIG. 6). In the super via 25 of the semiconductor device 10D, the barrier/liner dual-functional layer 252 only covers the side wall of the bulk via region 251, such that the bulk via region 251 is directly connected to the one of the metal lines 212 of the lower interconnect layer 21′.

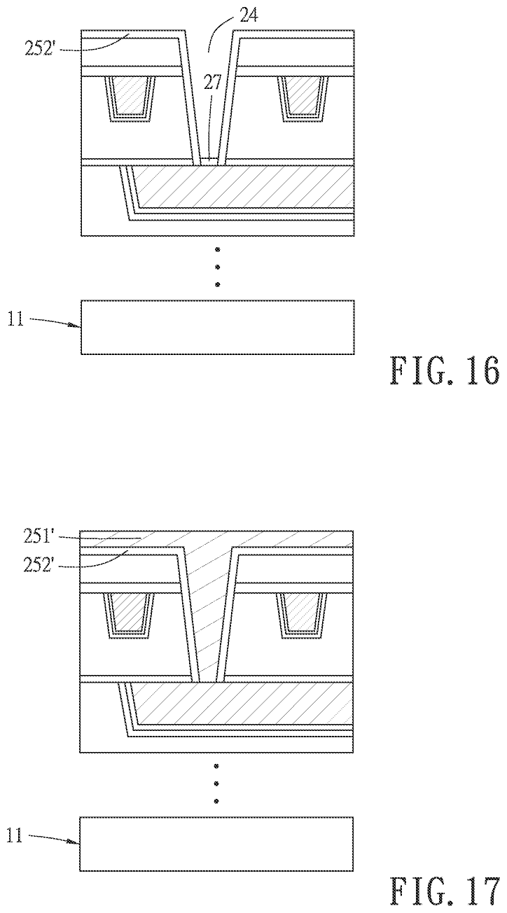

Referring to FIG. 1 and the examples illustrated in FIGS. 15 to 17, in some alternative embodiments, step S03 (i.e., formation of the super via 25) is performed by selectively forming a blocking layer 27 (for example, but not limited to, a self-assembled monolayer (SAM)) to block a portion of one of the metal lines 212 of the lower interconnect layer 21′ which is exposed to the via opening 24 (see FIG. 15), conformally depositing, with the exception of the blocking layer 27, the barrier/liner dual-functional material layer 252′ on the structure shown in FIG. 15 (see FIG. 16), removing the blocking layer 27 such that the portion of the one of the metal lines 212 of the lower interconnect layer 21′ is exposed to the via opening 24, depositing the bulk via material layer 251′ on the barrier/liner dual-functional material layer 252′ to fill the via opening 24, and removing excess of the bulk via material layer 251′ and excess of the barrier/liner dual-functional material layer 252′ over the dielectric layer 23 (see FIG. 17) by a planarization process (for example, but not limited to, the CMP process) to form the super via 25. Thereafter, the semiconductor device 10D shown in FIG. 14 is obtained after performing step S04 (i.e., formation of the interconnect layer 26 described above with reference to FIG. 6). In some embodiments, the blocking layer 27 is removed by using oxygen (O₂) plasma treatment, ozone (O₃) plasma treatment, other suitable treatments, or any combinations thereof.

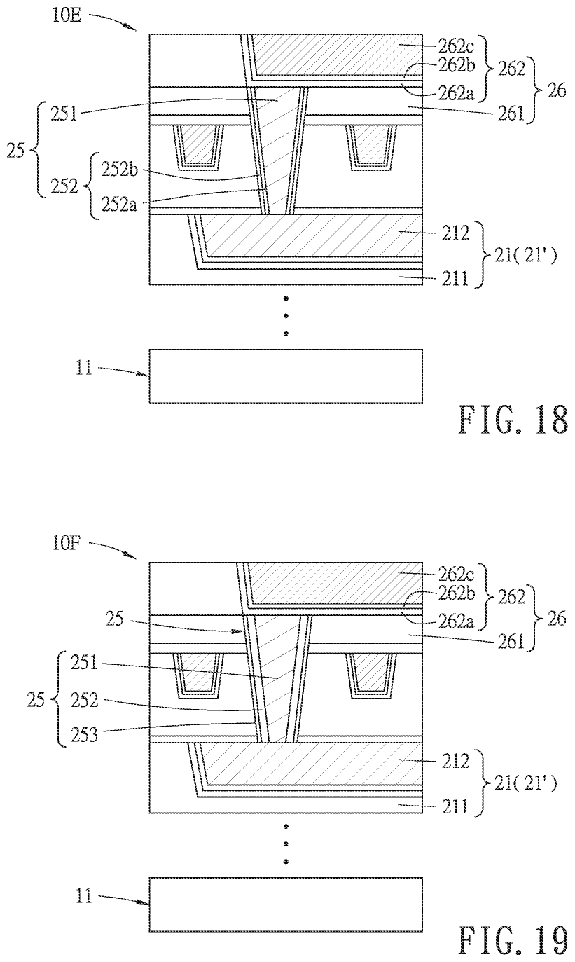

Referring to the example illustrated in FIG. 18, in a semiconductor device 10E in accordance with some alternative embodiments, the barrier/liner dual-functional layer 252 has a multi-layered configuration, and includes at least two sub-layers. In some embodiments, the barrier/liner dual-functional layer 252 includes the inner sub-layer 252a and the outer sub-layer 252b described above with reference to FIG. 7, except that in the barrier/liner dual-functional layer 252 of the super via 25 of the a semiconductor device 10E, the inner sub-layer 252a only covers the side wall of the bulk via region 251 and the outer sub-layer 252b only covers the side wall of the inner sub-layer 252a, such that the bulk via region 251 is directly connected to the one of the metal lines 212 of the lower interconnect layer 21′.

Referring to the example illustrated in FIG. 19, a semiconductor device 10F in accordance with some alternative embodiments has a configuration similar to that of the semiconductor device 10D shown in FIG. 14, except that the super via 25 of the semiconductor device 10F further includes the self-forming barrier layer 253 described above with reference to FIG. 8. The self-forming barrier layer 253 covers the side wall of the barrier/liner dual-functional layer 252 and is isolated from the bulk via region 251 by the barrier/liner dual-functional layer 252.

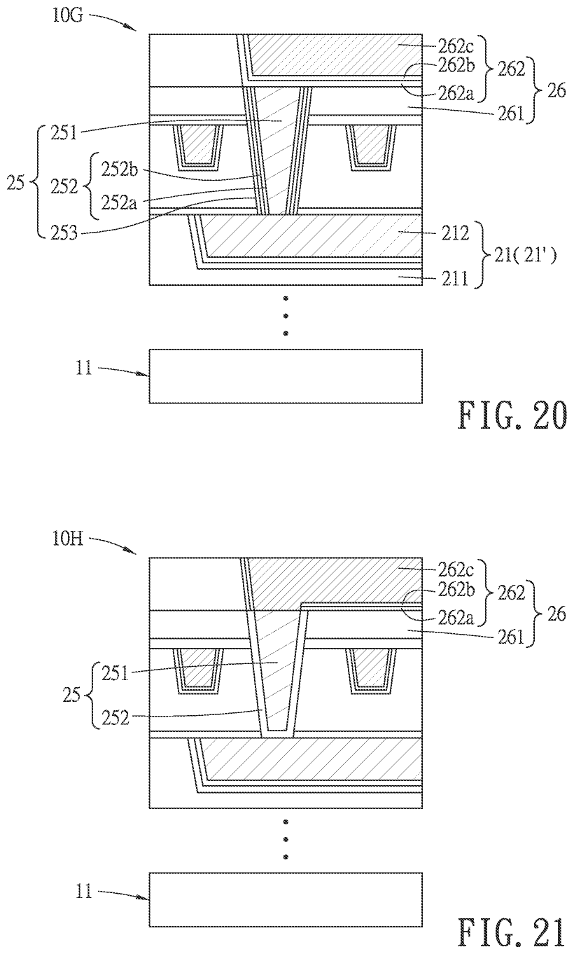

Referring to the example illustrated in FIG. 20, a semiconductor device 10G in accordance with some alternative embodiments has a configuration similar to that of the semiconductor device 10E shown in FIG. 18, except that the super via 25 of the semiconductor device 10G further includes the self-forming barrier layer 253 described above with reference to FIG. 8. The self-forming barrier layer 253 covers the side wall of the barrier/liner dual-functional layer 252 and is isolated from the bulk via region 251 by the barrier/liner dual-functional layer 252.

Referring to the example illustrated in FIG. 21, a semiconductor device 10H in accordance with some alternative embodiments has a configuration similar to that of the semiconductor device 10 shown in FIG. 6, except that the super via 25 in the semiconductor device 10H is directly connected to the bulk metal region 262c of a corresponding one of the metal lines 262 of the interconnect layer 26. In some embodiments, the interconnect layer 26 of the semiconductor device 10H may be formed by a single damascene process, which may includes an anisotropic etching process similar to that described above with references to FIGS. 10 and 11 or which may include formation of a blocking layer similar to that described above with reference to FIGS. 15 and 16. The details regarding the single damascene process, the anisotropic etching process, and the formation of the blocking layer are omitted for the sake of brevity.

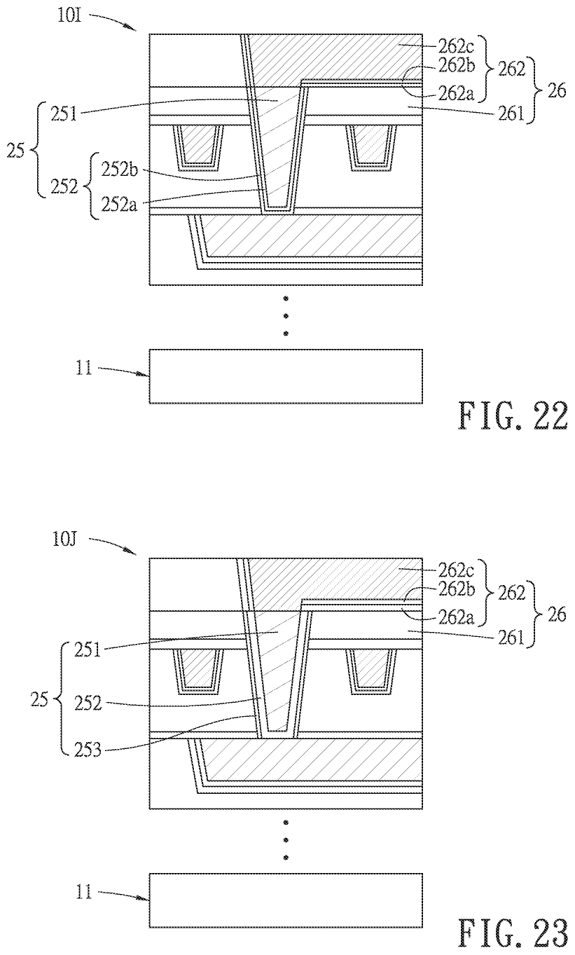

Referring to the example illustrated in FIG. 22, a semiconductor device 10I in accordance with some alternative embodiments has a configuration similar to that of the semiconductor device 10A shown in FIG. 7, except that the super via 25 in the semiconductor device 10I is directly connected to the bulk metal region 262c of a corresponding one of the metal lines 262 of the interconnect layer 26. In some embodiments, the interconnect layer 26 of the semiconductor device 10I may be formed by a single damascene process, which may includes an anisotropic etching process similar to that described above with references to FIGS. 10 and 11 or which may include formation of a blocking layer similar to that described above with reference to FIGS. 15 and 16. The details regarding the single damascene process, the anisotropic etching process, and the formation of the blocking layer are omitted for the sake of brevity.

Referring to the example illustrated in FIG. 23, a semiconductor device 10J in accordance with some alternative embodiments has a configuration similar to that of the semiconductor device 10B shown in FIG. 8, except that the super via 25 in the semiconductor device 10J is directly connected to the bulk metal region 262c of a corresponding one of the metal lines 262 of the interconnect layer 26. In some embodiments, the interconnect layer 26 of the semiconductor device 10J may be formed by a single damascene process, which may include an anisotropic etching process similar to that described above with references to FIGS. 10 and 11 or which may include formation of a blocking layer similar to that described above with reference to FIGS. 15 and 16. The details regarding the single damascene process, the anisotropic etching process, and the formation of the blocking layer are omitted for the sake of brevity.

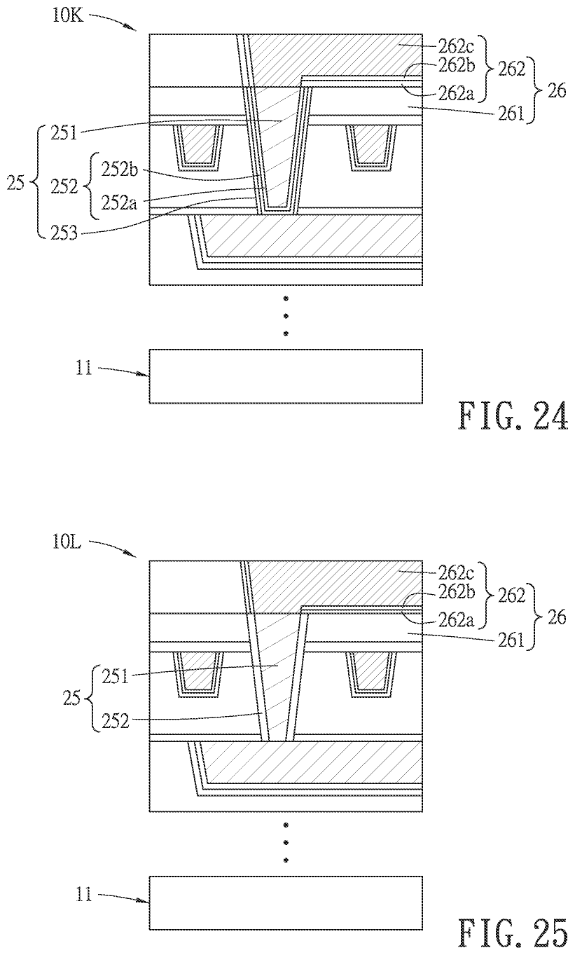

Referring to the example illustrated in FIG. 24, a semiconductor device 10K in accordance with some alternative embodiments has a configuration similar to that of the semiconductor device 10C shown in FIG. 9, except that the super via 25 in the semiconductor device 10K is directly connected to the bulk metal region 262c of a corresponding one of the metal lines 262 of the interconnect layer 26. In some embodiments, the interconnect layer 26 of the semiconductor device 10K may be formed by a single damascene process, which may include an anisotropic etching process similar to that described above with references to FIGS. 10 and 11 or which may include formation of a blocking layer similar to that described above with reference to FIGS. 15 and 16. The details regarding the single damascene process, the anisotropic etching process, and the formation of the blocking layer are omitted for the sake of brevity.

Referring to the example illustrated in FIG. 25, a semiconductor device 10L in accordance with some alternative embodiments has a configuration similar to that of the semiconductor device 10D shown in FIG. 14, except that the super via 25 in the semiconductor device 10L is directly connected to the bulk metal region 262c of a corresponding one of the metal lines 262 of the interconnect layer 26. In some embodiments, the interconnect layer 26 of the semiconductor device 10L may be formed by a single damascene process, which may include an anisotropic etching process similar to that described above with references to FIGS. 10 and 11 or which may include formation of a blocking layer similar to that described above with reference to FIGS. 15 and 16. The details regarding the single damascene process, the anisotropic etching process, and the formation of the blocking layer are omitted for the sake of brevity.

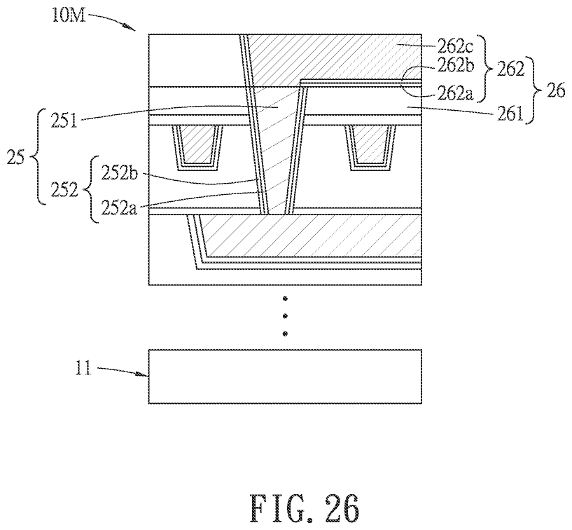

Referring to the example illustrated in FIG. 26, a semiconductor device 10M in accordance with some alternative embodiments has a configuration similar to that of the semiconductor device 10E shown in FIG. 18, except that the super via 25 in the semiconductor device 10M is directly connected to the bulk metal region 262c of a corresponding one of the metal lines 262 of the interconnect layer 26. In some embodiments, the interconnect layer 26 of the semiconductor device 10M may be formed by a single damascene process, which may include an anisotropic etching process similar to that described above with references to FIGS. 10 and 11 or which may include formation of a blocking layer similar to that described above with reference to FIGS. 15 and 16. The details regarding the single damascene process, the anisotropic etching process, and the formation of the blocking layer are omitted for the sake of brevity.

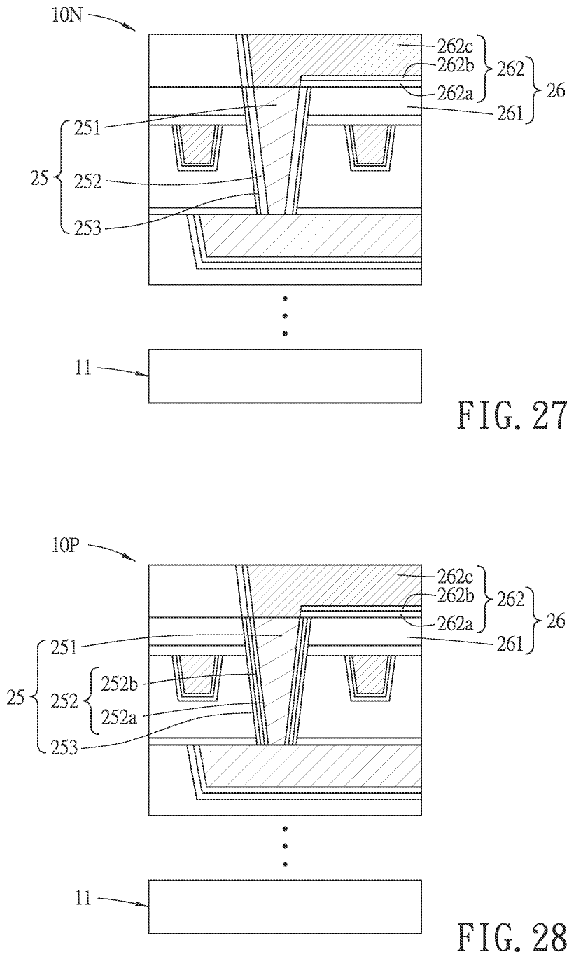

Referring to the example illustrated in FIG. 27, a semiconductor device 10N in accordance with some alternative embodiments has a configuration similar to that of the semiconductor device 10F shown in FIG. 19, except that the super via 25 in the semiconductor device 10N is directly connected to the bulk metal region 262c of a corresponding one of the metal lines 262 of the interconnect layer 26. In some embodiments, the interconnect layer 26 of the semiconductor device 10N may be formed by a single damascene process, which may include an anisotropic etching process similar to that described above with references to FIGS. 10 and 11 or which may include formation of a blocking layer similar to that described above with reference to FIGS. 15 and 16. The details regarding the single damascene process, the anisotropic etching process, and the formation of the blocking layer are omitted for the sake of brevity.

Referring to the example illustrated in FIG. 28, a semiconductor device 10P in accordance with some alternative embodiments has a configuration similar to that of the semiconductor device 10G shown in FIG. 20, except that the super via 25 in the semiconductor device 10P is directly connected to the bulk metal region 262c of a corresponding one of the metal lines 262 of the interconnect layer 26. In some embodiments, the interconnect layer 26 of the semiconductor device 10P may be formed by a single damascene process, which may include an anisotropic etching process similar to that described above with references to FIGS. 10 and 11 or which may include formation of a blocking layer similar to that described above with reference to FIGS. 15 and 16. The details regarding the single damascene process, the anisotropic etching process, and the formation of the blocking layer are omitted for the sake of brevity.

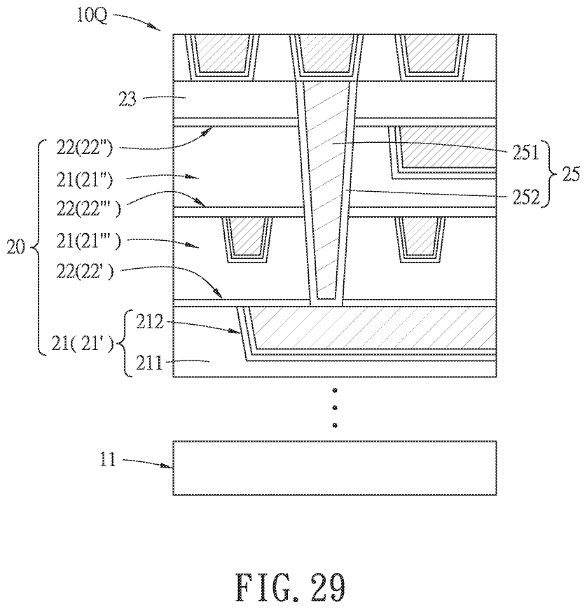

Referring to the example illustrated in FIG. 29, a semiconductor device 10Q in accordance with some alternative embodiments has a configuration similar to that of the semiconductor device 10 shown in FIG. 6, except that the multi-layered interconnect structure 20 in the semiconductor device 10Q further includes an intermediate interconnect layer 21′″ disposed on the lower etch stop layer 22′ opposite to the lower interconnect layer 21′, and an intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

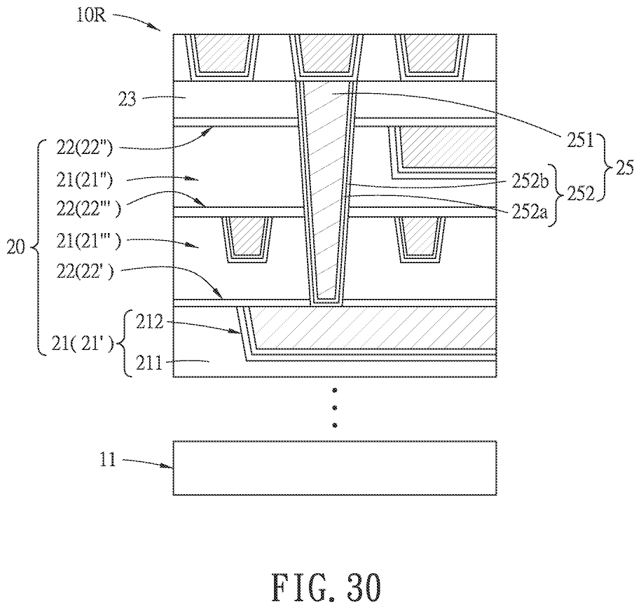

Referring to the example illustrated in FIG. 30, a semiconductor device 10R in accordance with some alternative embodiments has a configuration similar to that of the semiconductor device 10A shown in FIG. 7, except that the multi-layered interconnect structure 20 in the semiconductor device 10R further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

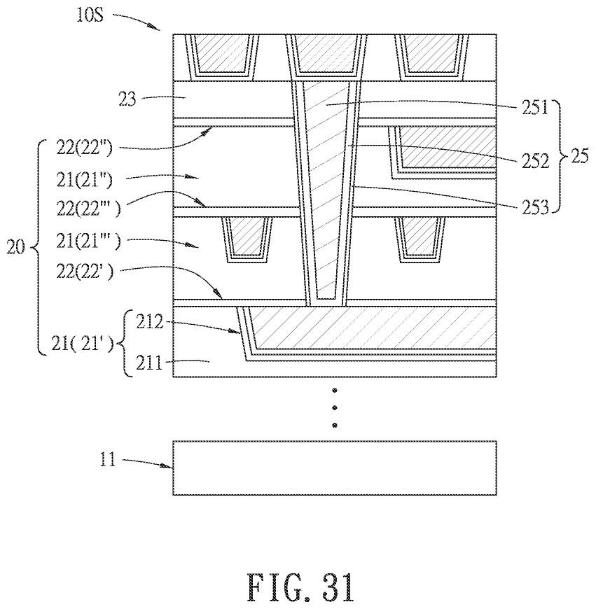

Referring to the example illustrated in FIG. 31, a semiconductor device 10S in accordance with some alternative embodiments has a configuration similar to that of the semiconductor device 10B shown in FIG. 8, except that the multi-layered interconnect structure 20 in the semiconductor device 10S further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

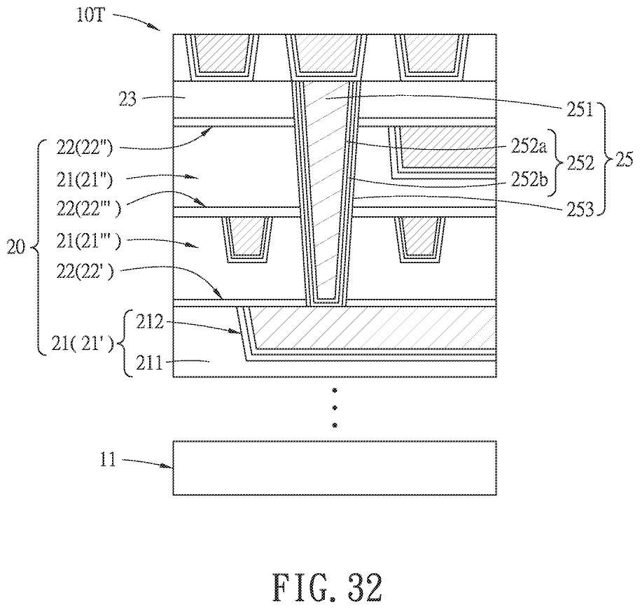

Referring to the example illustrated in FIG. 32, a semiconductor device 10T in accordance with some alternative embodiments has a configuration similar to that of the semiconductor device 10C shown in FIG. 9, except that the multi-layered interconnect structure 20 in the semiconductor device 10T further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

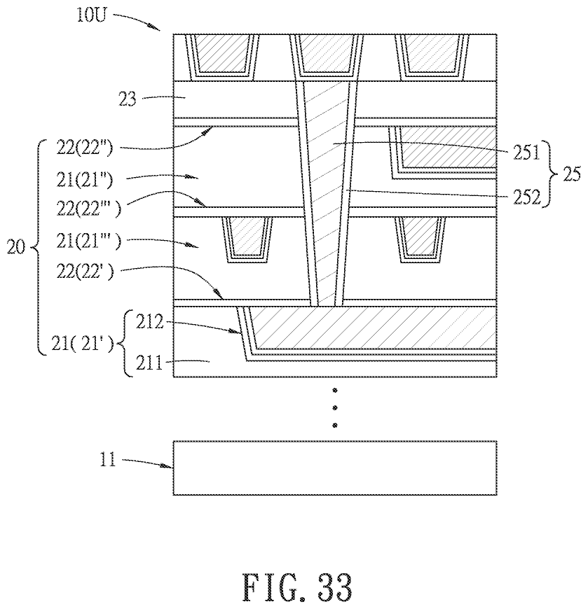

Referring to the example illustrated in FIG. 33, a semiconductor device 10U in accordance with some alternative embodiments has a configuration similar to that of the semiconductor device 10D shown in FIG. 14, except that the multi-layered interconnect structure 20 in the semiconductor device 10U further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

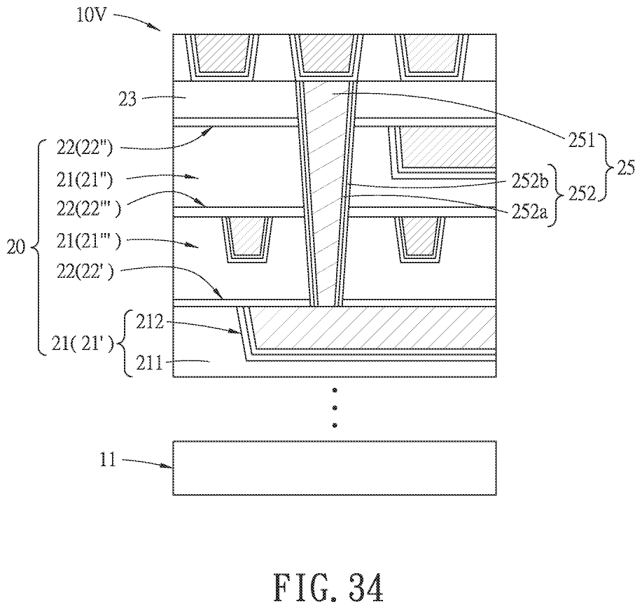

Referring to the example illustrated in FIG. 34, a semiconductor device 10V in accordance with some alternative embodiments has a configuration similar to that of the semiconductor device 10E shown in FIG. 18, except that the multi-layered interconnect structure 20 in the semiconductor device 10V further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

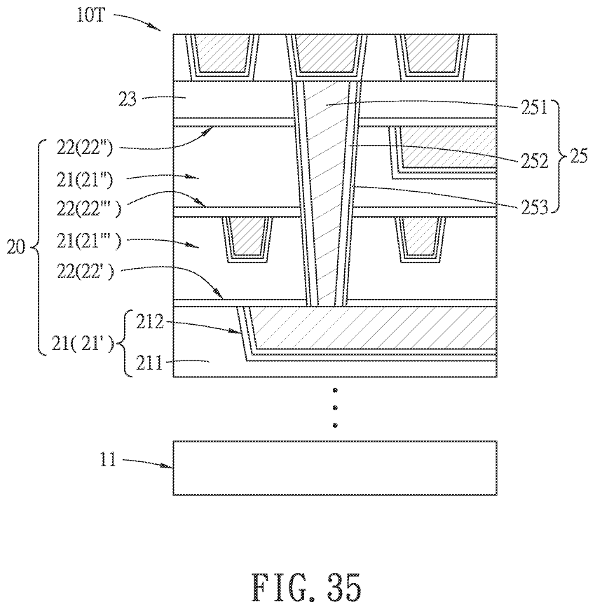

Referring to the example illustrated in FIG. 35, a semiconductor device 10W in accordance with some alternative embodiments has a configuration similar to that of the semiconductor device 10F shown in FIG. 19, except that the multi-layered interconnect structure 20 in the semiconductor device 10W further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

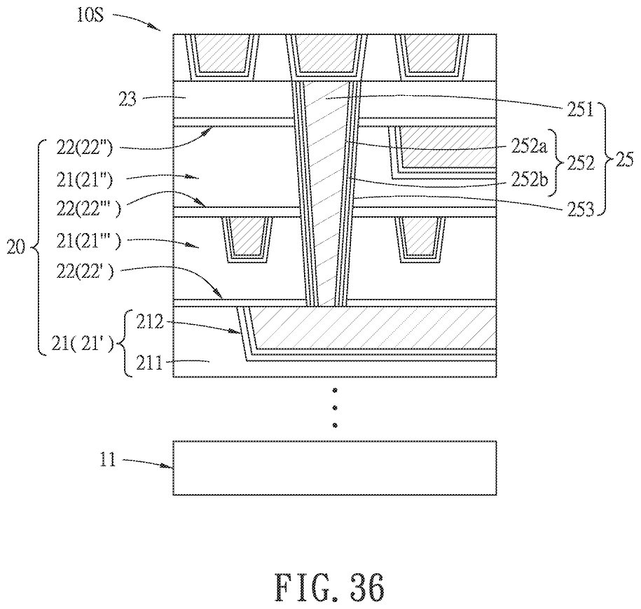

Referring to the example illustrated in FIG. 36, a semiconductor device 10S in accordance with some alternative embodiments has a configuration similar to that of the semiconductor device 10G shown in FIG. 20, except that the multi-layered interconnect structure 20 in the semiconductor device 10S further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

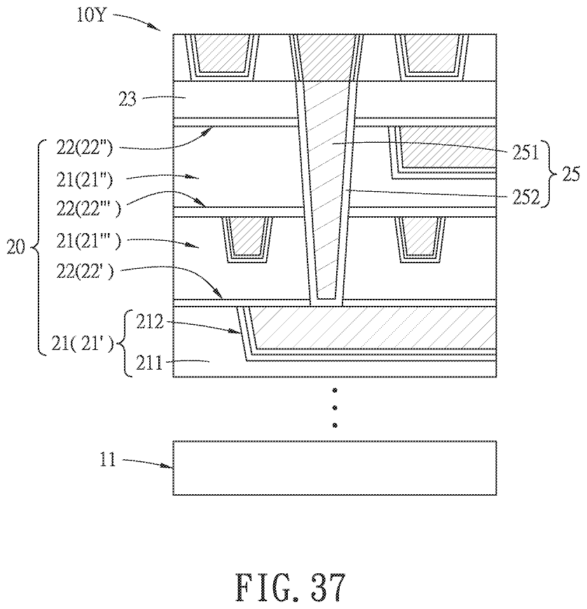

Referring to the example illustrated in FIG. 37, a semiconductor device 10Y in accordance with some alternative embodiments has a configuration similar to that of the semiconductor device 10H shown in FIG. 21, except that the multi-layered interconnect structure 20 in the semiconductor device 10Y further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

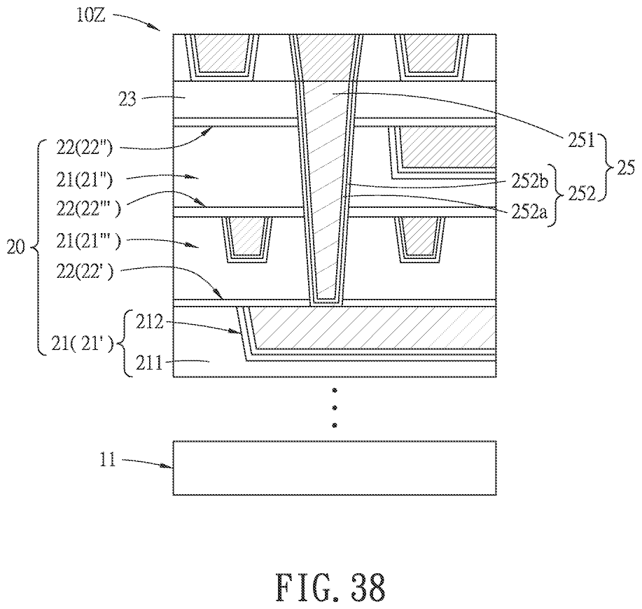

Referring to the example illustrated in FIG. 38, a semiconductor device 10Z in accordance with some alternative embodiments has a configuration similar to that of the semiconductor device 10I shown in FIG. 22, except that the multi-layered interconnect structure 20 in the semiconductor device 10Z further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

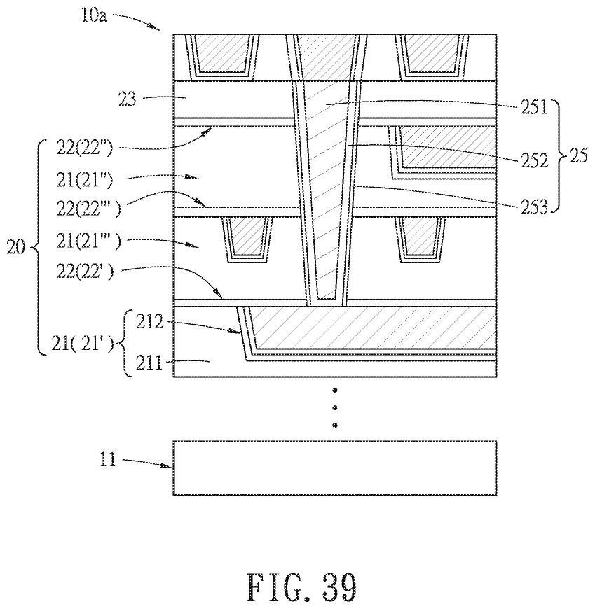

Referring to the example illustrated in FIG. 39, a semiconductor device 10a in accordance with some alternative embodiments has a configuration similar to that of the semiconductor device 10J shown in FIG. 23, except that the multi-layered interconnect structure 20 in the semiconductor device 10a further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

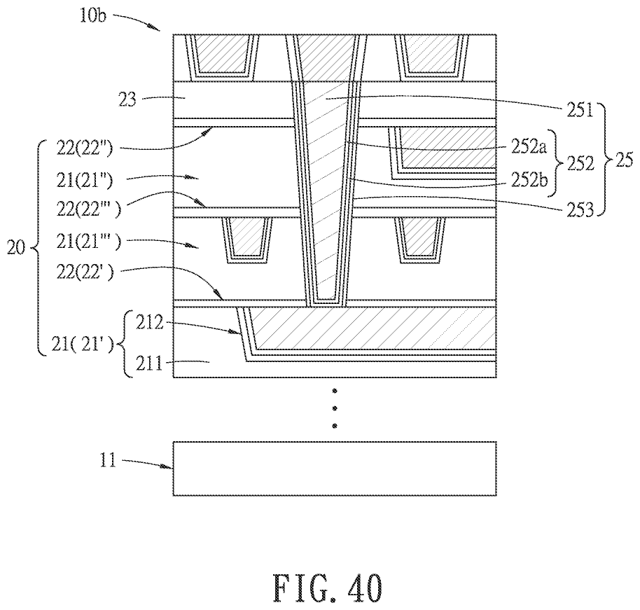

Referring to the example illustrated in FIG. 40, a semiconductor device 10b in accordance with some alternative embodiments has a configuration similar to that of the semiconductor device 10K shown in FIG. 24, except that the multi-layered interconnect structure 20 in the semiconductor device 10b further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

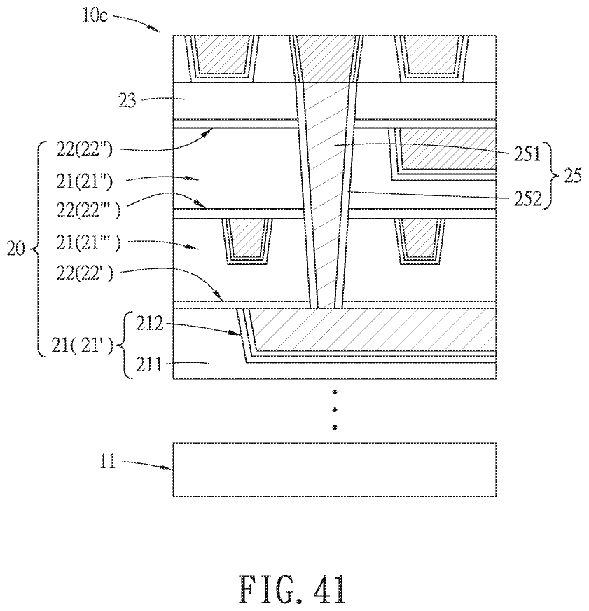

Referring to the example illustrated in FIG. 41, a semiconductor device 10c in accordance with some alternative embodiments has a configuration similar to that of the semiconductor device 10L shown in FIG. 25, except that the multi-layered interconnect structure 20 in the semiconductor device 10c further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

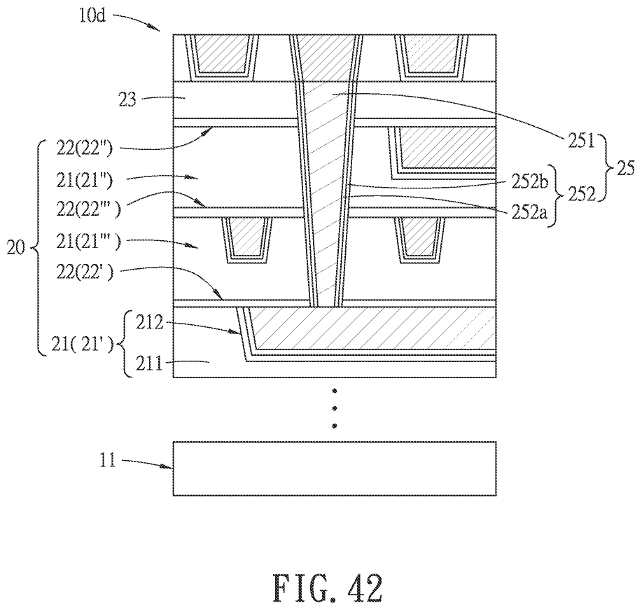

Referring to the example illustrated in FIG. 42, a semiconductor device 10d in accordance with some alternative embodiments has a configuration similar to that of the semiconductor device 10M shown in FIG. 26, except that the multi-layered interconnect structure 20 in the semiconductor device 10d further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

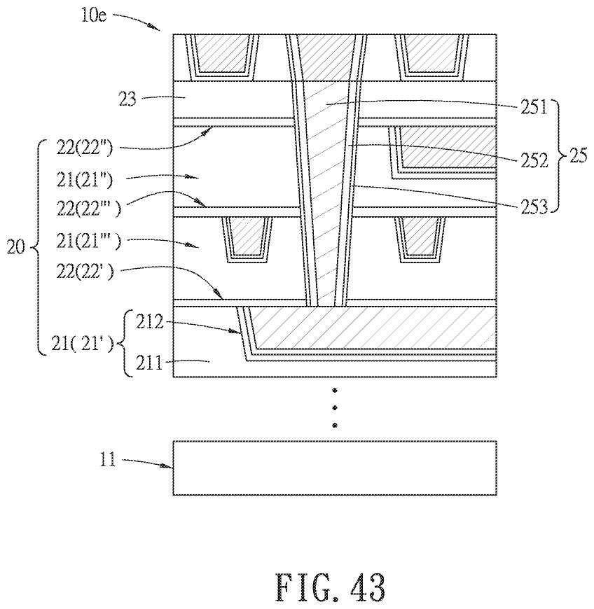

Referring to the example illustrated in FIG. 43, a semiconductor device 10e in accordance with some alternative embodiments has a configuration similar to that of the semiconductor device 10N shown in FIG. 27, except that the multi-layered interconnect structure 20 in the semiconductor device 10e further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

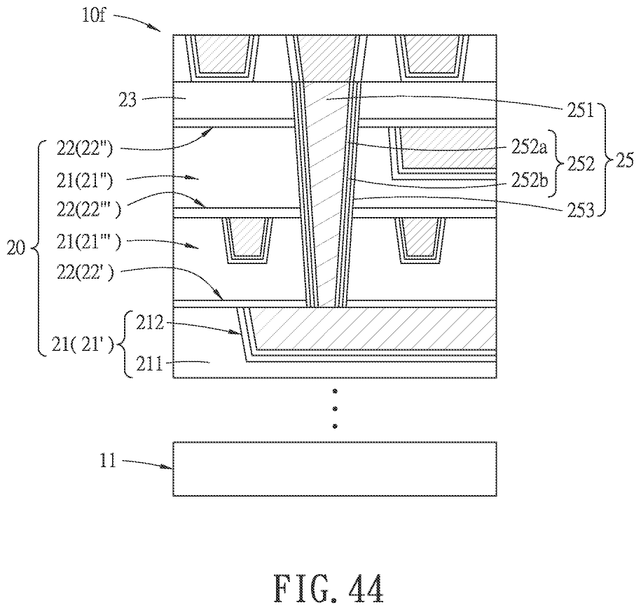

Referring to the example illustrated in FIG. 44, a semiconductor device 10f in accordance with some alternative embodiments has a configuration similar to that of the semiconductor device 10P shown in FIG. 28, except that the multi-layered interconnect structure 20 in the semiconductor device 10e further includes the intermediate interconnect layer 21′″ disposed on the lower etch stop layer 22′ opposite to the lower interconnect layer 21′, and the intermediate etch stop layer 22′″ disposed between the intermediate interconnect layer 21′″ and the upper interconnect layer 22″, and that the super via 25 penetrates the dielectric layer 23, the upper etch stop layer 22″, the upper interconnect layer 21″, the intermediate etch stop layer 22′ ″, the intermediate interconnect layer 21′″, and the lower etch stop layer 22′, and is connected to the one of the metal lines 212 of the lower interconnect layer 21′.

In a semiconductor device of the present disclosure, a super via is formed to penetrate at least one of a plurality of interconnect layers of a multi-layered interconnect structure and is connected to one of metal lines of one of the interconnect layers disposed below the at least one of the interconnect layers. In addition, the super via includes a barrier/liner dual-functional layer (i.e., a dual-functional layer serving as both a barrier layer and a liner layer) and may further include a self-forming barrier layer. The number of barrier and liner passing a multi-level metal routing can be reduced, bottom and top of the super via can be free of barrier, and the barrier/liner dual-functional layer occupies less space for forming the super via, thereby enlarging an effective volume for forming a bulk via region of the super via. Therefore, a via contact resistance can be lowered. In addition, since the super via is capable of reducing a routing wire length, a routing resistance can be reduced. Furthermore, the super via is formed with a metal alloy having strong resistance to electromigration, and the self-forming barrier layer is formed by diffusion of a metal component (serving as a doping component) of an alloy for forming the bulk via region of the super via, and thus the reliability of the semiconductor device of the present disclosure can be enhanced.

In accordance with some embodiments of the present disclosure, a method for manufacturing a semiconductor device includes: forming a multi-layered interconnect structure on a semiconductor substrate, the multi-layered interconnect structure including a plurality of interconnect layers and a plurality of etch stop layers alternately disposed on the semiconductor substrate, each of the interconnect layers including a plurality of metal lines separated from each other; forming a via opening to penetrate at least one of the interconnect layers so as to expose one of the metal lines of one of the interconnect layers disposed below the at least one of the interconnect layers; and forming a super via in the via opening to penetrate the at least one of the interconnect layers so that the super via is connected to the one of the metal lines of the one of the interconnect layers disposed below the at least one of the interconnect layers, the super via including a bulk via region and a barrier/liner dual-functional layer covering the bulk via region, the barrier/liner dual-functional layer including an alloy which includes a first metal component and a second metal component different from the first metal component, each of the first metal component and the second metal component including a metal selected from Co, Ru, Ta, Ti, W, Mo, Zn, Al, Mn, or Zr, a carbide of the metal, an oxide of the metal, a hydride of the metal, a nitride of the metal, a silicide of the metal, or combinations thereof.

In accordance with some embodiments of the present disclosure, the bulk via region is formed from a bulk via material layer including a first metal component which includes Cu, Ag, Au, Ni, Co, Fe, Ru, Os, Re, Ir, Pt, Pd, Rh, Al, W, Mo, or combinations thereof.

In accordance with some embodiments of the present disclosure, the bulk via material layer further includes a second metal component including a metal selected from Al, Mn, Ti, Zr, Hf, Nb, Ta, Mo, W, Zn, V, Cr, Sc, Fe, Y, or combinations thereof, a silicide of the metal, an oxide of the metal, or combinations thereof. The first metal component of the bulk via material layer serves as a main metal component. The second metal component of the bulk via material layer serves as a doping component.

In accordance with some embodiments of the present disclosure, the method for manufacturing a semiconductor device further includes: forming a self-forming barrier layer which covers the barrier/liner dual-functional layer and which is separated from the bulk via region by the barrier/liner dual-functional layer.

In accordance with some embodiments of the present disclosure, the self-forming barrier layer is formed by diffusing the second metal component of the bulk via material layer through the barrier/liner dual-functional layer.

In accordance with some embodiments of the present disclosure, the second metal component of the bulk via material layer is diffused through the barrier/liner dual-functional layer during deposition of the bulk via material layer to form the bulk via region.

In accordance with some embodiments of the present disclosure, the second metal component of the bulk via material layer is diffused through the barrier/liner dual-functional layer by an annealing process performed after the bulk via material layer is deposited.

In accordance with some embodiments of the present disclosure, the annealing process is performed at a temperature ranging from about 100° C. to about 1400° C.

In accordance with some embodiments of the present disclosure, the annealing process is a rapid thermal annealing process, a laser annealing process, a furnace annealing process, or combinations thereof.

In accordance with some embodiments of the present disclosure, a method for manufacturing a semiconductor device includes: forming a multi-layered interconnect structure on a semiconductor substrate, the multi-layered interconnect structure including a lower interconnect layer disposed on the semiconductor substrate and including a plurality of metal lines separated from each other, a lower etch stop layer disposed on the lower interconnect layer opposite to the semiconductor substrate, an upper interconnect layer disposed on the lower etch stop layer opposite to the lower interconnect layer and including a plurality of metal lines separated from each other, and an upper etch stop layer disposed on the upper interconnect layer opposite to the lower etch stop layer; forming a via opening to penetrate the upper etch stop layer, the upper interconnect layer, and the lower etch stop layer so as to expose one of the metal lines of the lower interconnect layer; and forming a super via in the via opening to penetrate the upper etch stop layer, the upper interconnect layer, and the lower etch stop layer so that the super via is connected to the one of the metal lines of the lower interconnect layer, the super via including a bulk via region and a barrier/liner dual-functional layer covering the bulk via region, the barrier/liner dual-functional layer including an alloy which includes a first metal component and a second metal component different from the first metal component, each of the first metal component and the second metal component including a metal selected from Co, Ru, Ta, Ti, W, Mo, Zn, Al, Mn, or Zr, a carbide of the metal, an oxide of the metal, a hydride of the metal, a nitride of the metal, a silicide of the metal, or combinations thereof.

In accordance with some embodiments of the present disclosure, the barrier/liner dual-functional layer is formed by depositing one of the first metal component and the second metal component, and adding the other one of the first metal component and the second metal component by an atom doping process after the deposition.

In accordance with some embodiments of the present disclosure, the method for manufacturing a semiconductor device further includes: performing a treatment to enhance barrier and liner properties of the barrier/liner dual-functional layer, the treatment including a gas soaking treatment, a precursor soaking treatment, a plasma treatment, or combinations thereof.

In accordance with some embodiments of the present disclosure, the treatment is performed using hydrogen gas, nitrogen gas, ammonia gas, hydrogen radical, methanol, silane, or a material having hydrogen bonds, hydroxyl bonds, nitrogen bonds, carbon bonds, silicon bonds, oxygen bonds, methyl bonds, or metal bonds.

In accordance with some embodiments of the present disclosure, the plasma treatment is performed using a power ranging from about 50 W to about 15 kW.

In accordance with some embodiments of the present disclosure, a semiconductor device includes a semiconductor substrate, a multi-layered interconnect structure, a super via, and an interconnect layer. The multi-layered interconnect structure is disposed on the semiconductor substrate, and includes a plurality of interconnect layers and a plurality of etch stop layers alternately disposed on the semiconductor substrate. Each of the interconnect layers includes a plurality of metal lines separated from each other. The super via penetrates at least one of the interconnect layers and is connected to one of the metal lines of one of the interconnect layers disposed below the at least one of the interconnect layers. The super via includes a bulk via region and a barrier/liner dual-functional layer covering the bulk via region. The barrier/liner dual-functional layer includes an alloy which includes a first metal component and a second metal component different from the first metal component. Each of the first metal component and the second metal component includes a metal selected from Co, Ru, Ta, Ti, W, Mo, Zn, Al, Mn, or Zr, a carbide of the metal, an oxide of the metal, a hydride of the metal, a nitride of the metal, a silicide of the metal, or combinations thereof. The interconnect layer is disposed on the multi-layered interconnect structure opposite to the semiconductor substrate, and includes a plurality of metal lines which are separated from each other and one of which is connected to the super via.

In accordance with some embodiments of the present disclosure, the barrier/liner dual-functional layer includes an inner sub-layer covering the bulk via region and an outer sub-layer covering the inner sub-layer. The inner sub-layer includes the first metal component. The outer sub-layer includes the second metal component. The barrier/liner dual-functional layer further includes an alloy which includes the first metal component and the second metal component and which is formed between the inner sub-layer and the outer sub-layer.

In accordance with some embodiments of the present disclosure, the bulk via region includes a first metal component including Cu, Ag, Au, Ni, Co, Fe, Ru, Os, Re, Ir, Pt, Pd, Rh, Al, W, Mo, or combinations thereof, and a second metal component including a metal selected from Al, Mn, Ti, Zr, Hf, Nb, Ta, Mo, W, Zn, V, Cr, Sc, Fe, Y, or combinations thereof, a silicide of the metal, an oxide of the metal, or combinations thereof.

In accordance with some embodiments of the present disclosure, the super via further includes a self-forming barrier layer which covers the barrier/liner dual-functional layer and which is separated from the bulk via region by the barrier/liner dual-functional layer.

In accordance with some embodiments of the present disclosure, the bulk via region includes Cu, Ag, Au, Ni, Co, Fe, Ru, Os, Re, Ir, Pt, Pd, Rh, Al, W, Mo, or combinations thereof, and the self-forming barrier layer includes a metal selected from Al, Mn, Ti, Zr, Hf, Nb, Ta, Mo, W, Zn, V, Cr, Sc, Fe, Y, or combinations thereof, a silicide of the metal, an oxide of the metal, or combinations thereof.

In accordance with some embodiments of the present disclosure, the bulk via region of the super via is directly connected to the one of the metal lines of the one of the interconnect layers disposed below the at least one of the interconnect layers.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a multi-layered interconnect structure on a semiconductor substrate, the multi-layered interconnect structure including a plurality of interconnect layers and a plurality of etch stop layers alternately disposed on the semiconductor substrate, each of the interconnect layers including a plurality of metal lines separated from each other;
forming a via opening to penetrate at least one of the interconnect layers so as to expose one of the metal lines of one of the interconnect layers disposed below the at least one of the interconnect layers; and
forming a super via in the via opening to penetrate the at least one of the interconnect layers so that the super via is connected to the one of the metal lines of the one of the interconnect layers disposed below the at least one of the interconnect layers, the super via including a bulk via region and a barrier/liner dual-functional layer covering the bulk via region, the barrier/liner dual-functional layer including an alloy which includes a first metal component and a second metal component different from the first metal component.

2. The method according to claim 1, wherein
the bulk via region is formed from a bulk via material layer including a first metal component which includes Cu, Ag, Au, Ni, Co, Fe, Ru, Os, Re, Ir, Pt, Pd, Rh, Al, W, Mo, or combinations thereof.

3. The method according to claim 2, wherein the bulk via material layer further includes a second metal component including a metal selected from Al, Mn, Ti, Zr, Hf, Nb, Ta, Mo, W, Zn, V, Cr, Sc, Fe, Y, or combinations thereof, a silicide of the metal, an oxide of the metal, or combinations thereof, the first metal component of the bulk via material layer serving as a main metal component, the second metal component of the bulk via material layer serving as a doping component.

4. The method according to claim 3, further comprising forming a self-forming barrier layer which covers the barrier/liner dual-functional layer and which is separated from the bulk via region by the barrier/liner dual-functional layer.

5. The method according to claim 4, wherein the self-forming barrier layer is formed by diffusing the second metal component of the bulk via material layer through the barrier/liner dual-functional layer.

6. The method according to claim 5, wherein the second metal component of the bulk via material layer is diffused through the barrier/liner dual-functional layer during deposition of the bulk via material layer to form the bulk via region.

7. The method according to claim 5, wherein the second metal component of the bulk via material layer is diffused through the barrier/liner dual-functional layer by an annealing process performed after the bulk via material layer is deposited.

8. The method according to claim 7, wherein the annealing process is performed at a temperature ranging from 100° C. to 1400° C.

9. The method according to claim 1, wherein, each of the first metal component and the second metal component includes a metal selected from Co, Ru, Ta, Ti, W, Mo, Zn, Al, Mn, or Zr, a carbide of the metal, an oxide of the metal, a hydride of the metal, a nitride of the metal, a silicide of the metal, or combinations thereof.

10. A method for manufacturing a semiconductor device, comprising:
forming a multi-layered interconnect structure on a semiconductor substrate, the multi-layered interconnect structure including
a lower interconnect layer disposed on the semiconductor substrate and including a plurality of metal lines separated from each other,
a lower etch stop layer disposed on the lower interconnect layer opposite to the semiconductor substrate,
an upper interconnect layer disposed on the lower etch stop layer opposite to the lower interconnect layer and including a plurality of metal lines separated from each other, and
an upper etch stop layer disposed on the upper interconnect layer opposite to the lower etch stop layer;
forming a via opening to penetrate the upper etch stop layer, the upper interconnect layer, and the lower etch stop layer so as to expose one of the metal lines of the lower interconnect layer; and
forming a super via in the via opening to penetrate the upper etch stop layer, the upper interconnect layer, and the lower etch stop layer so that the super via is connected to the one of the metal lines of the lower interconnect layer, the super via including a bulk via region and a barrier/liner dual-functional layer covering the bulk via region, the barrier/liner dual-functional layer including an alloy which includes a first metal component and a second metal component different from the first metal component.

11. The method according to claim 10, wherein the barrier/liner dual-functional layer is formed by depositing one of the first metal component and the second metal component, and adding the other one of the first metal component and the second metal component by an atom doping process after the deposition.

12. The method according to claim 10, further comprising performing a treatment to enhance barrier and liner properties of the barrier/liner dual-functional layer, the treatment including a gas soaking treatment, a precursor soaking treatment, a plasma treatment, or combinations thereof.

13. The method according to claim 12, wherein the treatment is performed using hydrogen gas, nitrogen gas, ammonia gas, hydrogen radical, methanol, silane, or a material having hydrogen bonds, hydroxyl bonds, nitrogen bonds, carbon bonds, silicon bonds, oxygen bonds, methyl bonds, or metal bonds.

14. The method according to claim 1, wherein the plasma treatment is performed using a power ranging from 50 W to 15 kW.

15. A semiconductor device, comprising:
a semiconductor substrate;
a multi-layered interconnect structure disposed on the semiconductor substrate, and including a plurality of interconnect layers and a plurality of etch stop layers alternately disposed on the semiconductor substrate, each of the interconnect layers including a plurality of metal lines separated from each other;
a super via penetrating at least one of the interconnect layers and connected to one of the metal lines of one of the interconnect layers disposed below the at least one of the interconnect layers, the super via including a bulk via region and a barrier/liner dual-functional layer covering the bulk via region, the barrier/liner dual-functional layer including an alloy which includes a first metal component and a second metal component different from the first metal component; and
an interconnect layer disposed on the multi-layered interconnect structure opposite to the semiconductor substrate, and including a plurality of metal lines which are separated from each other and one of which is connected to the super via.

16. The semiconductor device according to claim 15, wherein the barrier/liner dual-functional layer includes an inner sub-layer covering the bulk via region and an outer sub-layer covering the inner sub-layer, the inner sub-layer including the first metal component, the outer sub-layer including the second metal component, the barrier/liner dual-functional layer further including an alloy which includes the first metal component and the second metal component and which is formed between the inner sub-layer and the outer sub-layer.

17. The semiconductor device according to claim 15, wherein the bulk via region includes:
a first metal component including Cu, Ag, Au, Ni, Co, Fe, Ru, Os, Re, Ir, Pt, Pd, Rh, Al, W, Mo, or combinations thereof, and
a second metal component including a metal selected from Al, Mn, Ti, Zr, Hf, Nb, Ta, Mo, W, Zn, V, Cr, Sc, Fe, Y, or combinations thereof, a silicide of the metal, an oxide of the metal, or combinations thereof.

18. The semiconductor device according to claim 15, wherein the super via further includes a self-forming barrier layer which covers the barrier/liner dual-functional layer and which is separated from the bulk via region by the barrier/liner dual-functional layer.

19. The semiconductor device according to claim 18, wherein
the bulk via region includes Cu, Ag, Au, Ni, Co, Fe, Ru, Os, Re, Ir, Pt, Pd, Rh, Al, W, Mo, or combinations thereof, and
the self-forming barrier layer includes a metal selected from Al, Mn, Ti, Zr, Hf, Nb, Ta, Mo, W, Zn, V, Cr, Sc, Fe, Y, or combinations thereof, a silicide of the metal, an oxide of the metal, or combinations thereof.

20. The semiconductor device according to claim 15, wherein the bulk via region of the super via is directly connected to the one of the metal lines of the one of the interconnect layers disposed below the at least one of the interconnect layers.
